(19) United States
(12) Patent Application Publication
(10) Pub. No.: US 2016/0208113 A1
(43) Pub. Date: Jul. 21, 2016

(54) CONDUCTIVE ALUMINUM PASTE FOR LIGHTWEIGHT SOLAR CELL AND SOLAR CELL REQUIRING THE CONDUCTIVE ALUMINUM PASTE

(71) Applicant: PANCOLOUR INK CO., LTD, Taoyuan County (TW)

(72) Inventors: HSIANG-MING HSUEH, Taoyuan County (TW); YU-CHING PAI, Taoyuan County (TW)

(21) Appl. No.: 14/597,728

(22) Filed: Jan. 15, 2015

(51) Int. Cl. C09D 5/24; H01L 31/0224

(52) U.S. Cl. CPC C09D 5/24; H01L 31/022425

(57) ABSTRACT

A conductive aluminum paste which has a low printed weight and is suitable for use with a solar cell includes an aluminum powder, an organic carrier, and at least one of a vanadium source, a phosphorus source, and a molybdenum source. The vanadium source, phosphorus source, or molybdenum source accounts for a maximum 0.5% of the total weight of the conductive aluminum paste. A solar cell including the conductive aluminum paste is further provided. Due to its low printed weight, the conductive aluminum paste, coupled with the solar cell, maintains satisfactory electrical properties and pull, incurs low manufacturing cost, enhances water tolerance, and reduces warpage.

### FIELD OF THE INVENTION

The present invention relates to conductive aluminum pastes, and more particularly, to a conductive aluminum paste which contains a vanadium source, a phosphorus source, or a molybdenum source, and to a solar cell which requires the conductive aluminum paste.

### BACKGROUND OF THE INVENTION

A solar cell is a device for converting sunlight into output DC power. In this regard, silicon solar cells dominate solar power generation (and account for at least 80% of the throughput thereof). Conventional products produced by related manufacturers mostly have a substrate made of p-type silicon, wherein the n⁺ emitter is formed on the light-receiving side of the substrate by high-temperature phosphorous diffusion, so as to form a p-n junction diode. Then, an anti-reflection layer 60˜80 nm thick is formed on the n⁺ surface. Afterward, a front busbar and a slender gridlike silver electrode 30˜90 μm thick are formed on the anti-reflection layer by screen printing, whereas a back busbar is also formed on the other side (p-side) by screen printing, and then an aluminum paste is formed thereon to function as an aluminum source, so as to react with the silicon substrate in a high-temperature environment to form aluminum-silicon alloys and a back surface field (BSF) layer and therefore reduce the likelihood of recombination of minority carriers on the back side.

To achieve optimal efficiency and pull performance, it is common for manufacturers to apply an aluminum paste to a 6-inch silicon substrate by screen printing such that the aluminum paste functions as an aluminum source. In general, the required printed weight of the aluminum paste for use with a 6-inch silicon substrate is 1.3 g˜1.7 g. A printed weight less than 1.3 g has negative impacts as follows:
1. insufficient pull (for lack of sufficient molten aluminum to react with silicon in order to form aluminum-silicon alloys which are thick enough); and
2. insufficient efficiency (the BSF layer is not thick enough, and in consequence the likelihood of recombination of minority carriers on the back side remains high)

However, if the aluminum paste has a printed weight of less than 1.3 g, it will bring the following positive effects:
1. low manufacturing costs (low amount of the aluminum paste used);
2. satisfactory water tolerance (aluminum reacts with water to release hydrogen gas and therefore causes separation of modular layers after package lamination, and in consequence the service life of the module is shortened; hence, a reduction in the amount of aluminum paste in use prolongs the service life of the module); and
3. minimal warpage (aluminum differs from silicon in coefficient of thermal expansion; if aluminum-silicon alloys formed by lamination at a high temperature are too thick, they are likely to undergo warpage when their temperature drops back to a normal temperature, wherein aluminum has a coefficient of thermal expansion of 23 ppm/K, and silicon has a coefficient of thermal expansion of 2.5 ppm/K, indicating that aluminum and silicon differ from each other significantly in the coefficient of thermal expansion.)

Accordingly, it is imperative to provide a highly active solar power conductive aluminum paste which, given its low printed weight, maintains satisfactory electrical properties and pull, incurs low manufacturing cost, enhances water tolerance, and reduces warpage, which are intensively studied by researchers of solar power conductive aluminum pastes.

### SUMMARY OF THE INVENTION

In view of the aforesaid drawbacks of the prior art, it is an objective of the present invention to provide a conductive aluminum paste which has a low printed weight and is suitable for use with a solar cell and further provide the solar cell using the conductive aluminum paste, so as to overcome the drawbacks of the prior art—even though it has a low printed weight, a conventional solar power conductive aluminum paste cannot maintain satisfactory electrical properties and pull.

In order to achieve the above and other objectives, the present invention provides a conductive aluminum paste which has a low printed weight and is suitable for use with a solar cell. The conductive aluminum paste comprises an aluminum powder, an organic carrier, and at least one of a vanadium source, a phosphorus source, and a molybdenum source, wherein the total content of the vanadium source, the phosphorus source, or the molybdenum source is not higher than 0.5% of the total weight of the conductive aluminum paste.

Regarding the conductive aluminum paste, the vanadium source, the phosphorus source, and the molybdenum source are vanadium oxide, phosphate, and molybdenum oxide, respectively.

Regarding the conductive aluminum paste, the aluminum powder accounts for 65˜80%, and preferably 70˜76%, of the total weight of the conductive aluminum paste.

Regarding the conductive aluminum paste, the aluminum powder preferably comprises a fine aluminum powder with a particle diameter of less than 3 μm and a coarse aluminum powder with a particle diameter of 3˜7 μm, wherein the fine aluminum powder accounts for no more than 30% of the total weight of the conductive aluminum paste.

Regarding the conductive aluminum paste, the fine aluminum powder preferably accounts for 5˜25% of the total weight of the conductive aluminum paste.

Regarding the conductive aluminum paste, the organic carrier preferably accounts for 10˜30% of the total weight of the conductive aluminum paste.

Regarding the conductive aluminum paste, the organic carrier comprises a resin selected from the group consisting of ethyl cellulose, wood rosin, and polyacrylonitrile, and further comprises a solvent.

The conductive aluminum paste further comprises a glass powder with an average particle diameter of less than 6.0 μm and a content of not higher than 10% of the total weight of the conductive aluminum paste.

The conductive aluminum paste further comprises an additive selected from the group consisting of a dispersing agent, a leveling agent, a defoaming agent, a suspending agent, a thixotropy promoter, and a coupling agent.

In order to achieve the above and other objectives, the present invention further provides a solar cell which comprises the conductive aluminum paste.

The present invention provides a conductive aluminum paste which has a low printed weight and is suitable for use with a solar cell and further provides the solar cell using the conductive aluminum paste, such that the low printed weight renders it feasible to maintain satisfactory electrical properties and pull, cut manufacturing costs, enhance water tolerance, and reduce warpage.

### BRIEF DESCRIPTION OF THE DRAWINGS

nil

### DETAILED DESCRIPTION OF THE PREFERRED EMBODIMENTS

Objectives, features, and advantages of the present invention are hereunder illustrated with specific embodiments and described below.

The conductive aluminum paste of the present invention essentially comprises an aluminum powder, an organic carrier, and at least one of a vanadium source, a phosphorus source, and a molybdenum source, and further comprises a glass powder and various additives.

The aluminum powder accounts for 65˜80%, and preferably 70˜76%, of the total weight of the conductive aluminum paste.

The aluminum powder preferably has two particle diameters and therefore is generally provided in a combination of two forms, namely a fine aluminum powder and a coarse aluminum powder. For example, the fine aluminum powder has a particle diameter <3 μm, and the coarse aluminum powder has a particle diameter of 3˜7 μm. The fine aluminum powder accounts for no more than 30 wt %, and preferably 5˜25 wt %, of the total weight of the conductive aluminum paste.

The vanadium source, the phosphorus source, and the molybdenum source (i.e., including an additive of the aforesaid elements, such as vanadium oxide, phosphorus oxide, and molybdenum oxide) enhance aluminum paste reactivity and originate from an inorganic compound, a glass powder, an organic compound, or an additive, but the present invention is not limited thereto. The total content of the vanadium source, the phosphorus source, or the molybdenum source is not higher than 0.5% of the total weight of the conductive aluminum paste.

The organic carrier provides screen printing capability and drying strength. The organic carrier is synthesized from at least a resin and at least an organic solvent. The resin is ethyl cellulose, wood rosin, or polyacrylonitrile, but the present invention is not limited thereto. The solvent is an ester alcohol film-forming agent (Eastman Texanol®), terpineol, or di(ethylene glycol) monobutyl ether, but the present invention is not limited thereto. The organic carrier accounts for 10˜30 wt %, and preferably 20˜28 wt %, of the total weight of the conductive aluminum paste.

The glass powder increases the adhesion of the aluminum paste to the substrate and controls the reaction characteristics of the aluminum paste. The conductive aluminum paste of the present invention comprises one or more glass powders. The glass powders are formed by melting multiple elements or compounds at a high temperature. The glass powders each comprise Bi₂O₃, B₂O₃, SiO₂, Al₂O₃, or TiO₂, but the present invention is not limited thereto. Regarding the glass powders, their average particle diameter is less than 6.0 μm, and their content accounts for 0˜10 wt %, and preferably no more than 3%, of the total weight of the conductive aluminum paste.

The additive enhances the stability, printability, flatness, reactivity, and powder adhesion of the aluminum paste and is selectively a dispersing agent, a leveling agent, a defoaming agent, a suspending agent, a thixotropy promoter, or a coupling agent, but the present invention is not limited thereto. The additive accounts for 0˜5 wt %, and preferably 0˜1.3 wt %, of the total weight of the conductive aluminum paste.

The conductive aluminum paste in embodiments 1˜4 and comparisons 1˜2 of the present invention is prepared according to the ingredients and percentages shown in Table 1 below.

TABLE 1

| ingredient | material source | embodiment 1 | embodiment 2 | embodiment 3 | embodiment 4 | comparison 1 | comparison 2 |
|---|---|---|---|---|---|---|---|
| organic | 15% ETHOCEL Std 20 + 20% | 24.0% | 23.5% | 24.0% | 24.0% | 24.0% | 24.0% |
| carrier | terpineol + 65% di(ethylene | | | | | | |
| | glycol) monobutyl ether | | | | | | |
| glass | Nippon Electric Glass, | 2.4% | 2.4% | 2.4% | 2.4% | 2.4% | 2.4% |
| powder | QPB-045 glass powder | | | | | | |
| | (Bi—Zn—B series) | | | | | | |
| fine | Hunan Goldhorse | 14.7% | 14.7% | 14.7% | 14.7% | 14.7% | 14.7% |
| aluminum | FO103 | | | | | | |
| powder | | | | | | | |
| coarse | Hunan Goldhorse | 58.5% | 58.7% | 58.4% | 58.4% | 58.7% | 57.5% |
| aluminum | JM607 | | | | | | |
| powder | | | | | | | |
| phosphorus | P₂O₅ | 0.2% | | | | | 0.7% |
| source | TEGO ® Dispers 651 | | 0.5% | | | | |
| vanadium | V₂O₅ | | | | | | 0.5% |
| source | Okamoto Glass, VBS-12 glass | | | 0.3% | | | |
| | powder (V—Ba—Si series) | | | | | | |
| molybdenum | MoO₃ | | | | 0.3% | | |
| source | | | | | | | |
| promoter | 0.2% Elementis Specialties | 0.2% | 0.2% | 0.2% | 0.2% | 0.2% | 0.2% |
| | Thiaxatrol ST | | | | | | |
| total | | 100.0% | 100.0% | 100.0% | 100.0% | 100.0% | 100.0% |

### Embodiment 1

The conductive aluminum paste of embodiment 1 is prepared by following the steps below:

Step 1 (organic carrier production): introduce ethyl cellulose (ETHOCEL Std 20)/terpineol/di(ethylene glycol) monobutyl ether at a ratio of 15:20:65 to a reactor and stir the aforesaid compounds in the reactor by an oil bath of 110° C. at 300 rpm for at least three hours until they dissolve fully.

Step 2: add a glass powder, an aluminum powder, and the like to the organic carrier produced in step 1 in accordance with the ingredients and percentages shown in Table 1, so as to produce 300 g of mixed aluminum paste.

Step 3:

stir the mixed aluminum paste produced in step 2 for three minutes with a high-speed blender until it is sufficiently mixed, and then grind it with a three-roll mill (model no. Exakt 80E) thrice to obtain the conductive aluminum paste with a viscosity of 30˜50 Pa•s and average particle diameter of 8 μm.

### Embodiments 2-4 and Comparisons 1˜2

Embodiments 2˜4 and comparisons 1˜2 prepare the conductive aluminum paste in the same way as embodiment 1, except that step 2 of embodiments 2˜4 and comparisons 1˜2 is carried out with ingredients and percentages different from that shown in Table 1.

Test

A solar cell is produced, using the conductive aluminum paste produced in embodiments 1˜4 and comparisons 1˜2, by following the steps below.

Step 1 (printing): apply back silver paste and front silver paste to the back and front of a 6-inch silicon substrate by screen printing, respectively, dry the silicon substrate which has thereon the back silver paste and front silver paste in an oven at 200° C., apply the conductive aluminum paste produced in embodiments 1˜4 and comparisons 1˜2 to a portion of the back of the silicon substrate, wherein the portion of the back of the silicon substrate is not covered with the back silver paste, such that the conductive aluminum paste overlaps the back silver paste partially, adjust printing parameters and screen printing sieve number so as to control different printed weights, and put the silicon substrate in the oven at 200° C. again, thereby producing a printed silicon substrate to be sintered.

Step 2 (sintering): when the drying step is done, put the to-be-sintered printed silicon substrate produced in step 1 in an infrared fast sintering furnace (Despatch CF furnace) for sintering, so as to produce a solar cell. In the sintering step, related parameters are configured as follows: Z1/Z2/Z3/Z4/Z5/Z6/speed=500° C./550° C./600° C./680° C./830° C./930° C./230 ipm (inch/minute), wherein the infrared fast sintering furnace conveys the to-be-sintered printed silicon substrate with a conveyor belt so that the to-be-sintered printed silicon substrate passes through different temperature zones, such as Z1˜Z6. The conveying speed of the conveyor belt is 230 ipm.

By following the above steps, a solar cell is produced, using the conductive aluminum pastes of embodiments 1˜4 and comparisons 1˜2. Then, the solar cell thus produced is tested in terms of properties as follows:

Solar photovoltaic conversion efficiency: simulate a test system with a solar cell plate to test the solar photovoltaic conversion efficiency of the solar cell, wherein the test instrument is QuickSun 120CA manufactured by Finland-based Endeas.

Pull: cut EVA film into 1cm×10 cm strips, put the EVA film strips on the back of the solar cell, allow the EVA film strips on the back of the solar cell to undergo a hot-pressing process thrice at 150° C. with a laminator, such that the EVA film strips are hot-pressed against the back of the solar cell, measure and determine the maximum pull between the EVA film and the solar cell with a pull gauge. If the maximum pull is determined to be less than 1 kgf, the solar cell will be deemed defective.

Water tolerance: put 500 cc of deionized water in a beaker, heat the beaker on a heating plate until the water temperature reaches 75° C., and put the solar cell flat at the bottom of the beaker. If bubbles last for 10 minutes, the solar cell will be deemed defective.

Warpage: after being sintered, the solar cell is cooled down for 1 hour, and then its thickness is measured with a thickness gauge; if its thickness is found to be more than 1.8 mm, the solar cell will be deemed defective.

Aluminum bump: after being sintered, the solar cell has its surface marked by bumps similar in appearance to that found on the skins of Citrus fruits. The presence of aluminum bumps on the surface of the solar cell indicates that the solar cell is defective.

The test results of the aforesaid properties are presented in Table 2 below.

TABLE 2

| | phosphorus | vanadium | molybdenum | printed | efficiency | | water | | aluminum |
|---|---|---|---|---|---|---|---|---|---|
| group | source | source | source | weight | (%) | pull (kgf) | tolerance | warpage | bumps |
| embodiment 1 | 0.2% P₂O₅ | — | — | 1.5 | 19.5 | OK | OK | OK | OK |
| | | | | 1.2 | 19.51 | OK | OK | OK | OK |
| | | | | 0.8 | 19.5 | OK | OK | OK | OK |
| embodiment 2 | 0.5% TEGO ® | — | — | 1.5 | 19.48 | OK | OK | OK | OK |
| | Dispers 651 | | | 1.2 | 19.48 | OK | OK | OK | OK |
| | | | | 0.8 | 19.49 | OK | OK | OK | OK |
| embodiment 3 | — | 0.3% | — | 1.5 | 19.52 | OK | OK | OK | OK |
| | | V₂O₅ | | 1.2 | 19.5 | OK | OK | OK | OK |
| | | | | 0.8 | 19.53 | OK | OK | OK | OK |
| embodiment 4 | — | — | 0.3% MoO₃ | 1.5 | 19.44 | OK | OK | OK | OK |
| | | | | 1.2 | 19.45 | OK | OK | OK | OK |
| | | | | 0.8 | 19.43 | OK | OK | OK | OK |
| comparison 1 | — | — | — | 1.5 | 19.50 | OK | defective | OK | OK |
| | | | | 1.3 | 19.35 | defective | OK | OK | OK |
| | | | | 1.2 | 18.90 | defective | OK | OK | OK |
| comparison 2 | 0.7% P₂O₅ | 0.5% | — | 1.5 | 19.52 | OK | OK | defective | defective |
| | | V₂O₅ | | 1.3 | 19.45 | OK | OK | defective | defective |
| | | | | 1.2 | 19.40 | OK | OK | defective | defective |

The printed weight shown in Table 2 refers to the printed weight (g/6-inch silicon substrate) of the conductive aluminum paste on a 6-inch silicon substrate, wherein the 6-inch silicon substrate has a printed area of 235 cm², which can be converted into unit area printed weight (mg/cm²) as follows:
1.5 g/6-inch silicon substrate=6.3 mg/cm²
1.3 g/6-inch silicon substrate=5.5 mg/cm²
1.2 g/6-inch silicon substrate=5.0 mg/cm²
0.8 g/6-inch silicon substrate=3.4 mg/cm²

Referring to Table 2, unsatisfactory results of the tests are highlighted in bold font. The test results shown in Table 2 reveal the following: compared with comparison 1 which lacks any vanadium source, phosphorus source or molybdenum source, embodiments 1˜4 yield better test results in terms of solar photovoltaic conversion efficiency, pull, and water tolerance, the solar cell of comparison 1 is characterized in that the solar photovoltaic conversion efficiency markedly decreases from 19.50% to 19.35% when the printed weight of the conductive aluminum paste decreases from 1.5 g to 1.3 g and decreases further to 18.90% when the printed weight decreases to 1.2 g. By contrast, the solar cell of embodiments 1˜4 is characterized in that the solar photovoltaic conversion efficiency does not change significantly even though the printed weight of the conductive aluminum paste decreases from 1.5 g to 1.2 g or even to 0.8 g, thereby proving that the conductive aluminum paste of the present invention can have a low printed weight without compromising the solar photovoltaic conversion efficiency of the solar cell.

Regarding pull and water tolerance, the solar cell of comparison 1 manifests satisfactory pull and unsatisfactory water tolerance when the printed weight is 1.5 g, and manifests satisfactory water tolerance and unsatisfactory pull when the printed weight is 1.3 g or 0.2 g, to therefore prove the following: given a low printed weight of a conductive aluminum paste, the solar cell with the conductive aluminum paste which does not contain any vanadium source, phosphorus source or molybdenum source has an increase in water tolerance at the expense of pull properties. By contrast, the solar cell of embodiments 1˜4 manifests satisfactory pull and water tolerance when the printed weight of the conductive aluminum paste is 1.5 g, and manifests satisfactory pull when the printed weight of the conductive aluminum paste decreases from 1.5 g to 0.8 g, to therefore prove the following: the conductive aluminum paste of the present invention can have a low printed weight to therefore maintain satisfactory water tolerance without reducing the pull.

The conductive aluminum paste of the present invention can have a low printed weight in order to cut per-watt production costs of solar cells.

The test results shown in Table 2 reveal the following: compared with comparison 2 in which a vanadium source, phosphorus source, or molybdenum source with a concentration of larger than 0.5 wt % is included, embodiments 1˜4, in which a vanadium source, phosphorus source, or molybdenum source has a concentration which is equal to or less than 0.5 wt % is included, is characterized in that the solar cell yields better test results in terms of solar photovoltaic conversion efficiency, warpage, and aluminum bumps. Hence, the concentration of the vanadium source, phosphorus source, or molybdenum source in the conductive aluminum paste of the present invention is preferably ≦0.5 wt %.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall into the scope of the present invention. Accordingly, the legal protection for the present invention should be defined by the appended claims.

What is claimed is:

1. A conductive aluminum paste for a lightweight solar cell, comprising:
an aluminum powder;
an organic carrier including a resin and a solvent; and
at least one of a vanadium source, a phosphorus source, and a molybdenum source, whose content is not higher than 0.5% of a total weight of the conductive aluminum paste.

2. The conductive aluminum paste of claim 1, wherein the vanadium source, the phosphorus source, and the molybdenum source are vanadium oxide, phosphorus oxide, and molybdenum oxide, respectively.

3. The conductive aluminum paste of claim 1, wherein the aluminum powder comprises
a fine aluminum powder with a particle diameter less than 3 μm; and
a coarse aluminum powder with a particle diameter of 3˜7 μm, wherein the fine aluminum powder accounts for no more than 30% of a total weight of the conductive aluminum paste.

4. The conductive aluminum paste of claim 3, wherein the fine aluminum powder accounts for 5˜25% of the total weight of the conductive aluminum paste.

5. The conductive aluminum paste of claim 1, wherein the organic carrier accounts for 10˜30% of the total weight of the conductive aluminum paste.

6. The conductive aluminum paste of claim 5, wherein the organic carrier accounts for 20˜28% of the total weight of the conductive aluminum paste.

7. The conductive aluminum paste of claim 6, wherein the resin in the organic carrier comprises one selected from the group consisting of ethyl cellulose, wood rosin, and polyacrylonitrile.

8. The conductive aluminum paste of claim 1, further comprising a glass powder having an average particle diameter less than 6.0 μm and a content not higher than 10% of the total weight of the conductive aluminum paste.

9. The conductive aluminum paste of claim 1, further comprising an additive selected from the group consisting of a dispersing agent, a leveling agent, a defoaming agent, a suspending agent, a thixotropy promoter, and a coupling agent.

10. A solar cell, comprising the conductive aluminum paste of claim 1.
